(19) United States
(12) Patent Application Publication
(10) Pub. No.: US 2024/0122053 A1
(43) Pub. Date: Apr. 11, 2024

(54) DISPLAY PANEL MANUFACTURING METHOD AND APPARATUS

(71) Applicant: Samsung Display Co., Ltd., Yongin-si (KR)

(72) Inventors: SUNGJUN KIM, Yongin-si (KR); WOO HYUK KWON, Yongin-si (KR); JAE MYOUN DO, Yongin-si (KR); BONG HO SUL, Yongin-si (KR); SEUNG NOH LEE, Yongin-si (KR); GYEOM UK KIM, Yongin-si (KR); YOUNG-BAE KIM, Yongin-si (KR); YOUNG-JUN YUN, Yongin-si (KR); KYUNGCHEOL LEE, Yongin-si (KR); KYUNGSEOK HEO, Yongin-si (KR); GUN-A HWANG, Yongin-si (KR); MINHO HWANG, Yongin-si (KR)

(21) Appl. No.: 18/378,650

(22) Filed: Oct. 10, 2023

(30) Foreign Application Priority Data
Oct. 11, 2022 (KR) 10-2022-0129537

(51) Int. Cl. H10K 71/60; B41M 5/00; H10K 59/12

(52) U.S. Cl. CPC H10K 71/611; B41M 5/0082; H10K 59/1201

(57) ABSTRACT

Provided are display panel manufacturing method and apparatus. The display panel manufacturing method includes detecting a machining target area of a bottom layer, removing an area, overlapping the machining target area, of a top layer, emitting a laser beam to the machining target area of the bottom layer to provide a bottom pattern from the machining target area, and providing a compensation pattern in the removed area of the top layer.

### CROSS-REFERENCE TO RELATED APPLICATION

This application claims priority to Korean Patent Application No. 10-2022-0129537 filed in the Korean Intellectual Property Office on Oct. 11, 2022, and all the benefits accruing therefrom under 35 U.S.C. § 119, the content of which in its entirety is herein incorporated by reference.

### BACKGROUND

The present disclosure relates to a display panel manufacturing method and apparatus, and more particularly to a display panel manufacturing method including a laser patterning process and a display panel manufacturing apparatus including a laser module.

A display device includes a plurality of pixels and a driving circuit (e.g., a scan driving circuit or a data driving circuit) for controlling the plurality of pixels. Each of the plurality of pixels includes a display element and a pixel driving circuit configured to control the display element. The pixel driving circuit may include a plurality of transistors organizationally in contact with each other.

The pixel driving circuit may be provided through a plurality of deposition processes and a plurality of photolithography processes.

### SUMMARY

The present disclosure provides a display panel manufacturing method that may correct errors in photolithography processes.

The present disclosure also provides a display panel manufacturing apparatus used for the display panel manufacturing method.

In an embodiment, a display panel manufacturing method includes: detecting a machining target area of a bottom layer; removing an area overlapping the machining target area of a top layer disposed on the bottom layer; removing an area overlapping the machining target area of an insulation layer disposed on the bottom layer; emitting a laser beam to the machining target area of the bottom layer to form a bottom pattern from the machining target area; forming an insulation pattern in the removed area of the insulation layer; and forming a compensation pattern in the removed area of the top layer, wherein the bottom layer includes a semiconductor material or an electrically conductive material, and wherein the top layer includes an electrically conductive material.

In an embodiment, the bottom layer may include the semiconductor material, the bottom pattern may include a channel area of a transistor, and the compensation pattern may include a control electrode of the transistor.

In an embodiment, the bottom pattern may have a curved shape in a plan view.

In an embodiment, the insulation pattern may have a substantially same thickness as that of the insulation layer.

In an embodiment, the insulation pattern may include a substantially same material as that of the insulation layer.

In an embodiment, the compensation pattern may include a material having a higher electrical conductivity than the top layer.

In an embodiment, the compensation pattern may constitute a portion of a scan line.

In an embodiment, a line-width of the scan line may be about 3 μm or smaller.

In an embodiment, the forming of the insulation pattern may include: providing an insulation ink to the removed area of the insulation layer; and curing the insulation ink.

In an embodiment, the insulation ink may be provided from an electrohydrodynamic (EHD) insulation ink nozzle.

In an embodiment, the electrohydrodynamic insulation ink nozzle may be spaced apart from the insulation layer by about 5 μm or greater.

In an embodiment, the insulation ink may include silicon oxide, silicon nitride, or silicon oxynitride.

In an embodiment, the forming of the compensation pattern may include: providing a metal ink to the removed area of the top layer; and curing the metal ink.

In an embodiment, the metal ink may be provided from an electrohydrodynamic metal ink nozzle.

In an embodiment, the electrohydrodynamic metal ink nozzle may be spaced apart from the top layer by about 5 μm or greater.

In an embodiment, the metal ink may include silver.

In an embodiment, a display panel manufacturing apparatus includes: a body part; a camera module combined to the body part; a laser module combined to the body part; a curing module combined to the body part; an electrohydrodynamic insulation ink nozzle configured to provide an insulation ink; and an electrohydrodynamic metal ink nozzle configured to provide a metal ink, wherein the electrohydrodynamic insulation ink nozzle is combined to the body part so as to be inclined with respect to a work substrate at an angle of about 30° to about 60°, and wherein the electrohydrodynamic metal ink nozzle is combined to the body part so as to be inclined with respect to the work substrate at an angle of about 30° to about 60°.

In an embodiment, with respect to the work substrate, a slope of the electrohydrodynamic insulation ink nozzle may be substantially same as that of the electrohydrodynamic metal ink nozzle.

In an embodiment, when viewed on the work substrate, the curing module may be disposed between the electrohydrodynamic insulation ink nozzle and the electrohydrodynamic metal ink nozzle.

In an embodiment, the display panel manufacturing apparatus may further include: a gantry movable in a first direction, wherein the body part is combined to the gantry so as to be movable in a second direction that is orthogonal to the first direction.

### BRIEF DESCRIPTION OF THE FIGURES

The accompanying drawings are included to provide a further understanding of the inventive concept, and are incorporated in and constitute a part of this specification. The drawings illustrate embodiments of the inventive concept and, together with the description, serve to explain principles of the inventive concept. In the drawings:

FIG. 1 is a perspective view of a display panel according to an embodiment;

FIG. 2 is an equivalent circuit diagram of a pixel according to an embodiment;

FIG. 3 is a cross-sectional view corresponding to a pixel of a display panel according to an embodiment;

FIG. 4 is a plan view of a pixel according to an embodiment;

FIGS. 5A and 5B are plane views according to a lamination order of patterns included in a pixel according to an embodiment;

FIG. 5C is a plan view of a bottom layer including a machining target area;

FIG. 6 is a plan view of a manufacturing apparatus according to an embodiment;

FIGS. 7A to 7C show a head assembly of a manufacturing apparatus according to an embodiment; and

FIGS. 8A to 8J show a display panel manufacturing method according to an embodiment.

### DETAILED DESCRIPTION

It will be understood that when an element or layer is referred to as being “on”, “connected to” or “coupled to” another element or layer, it can be directly on, connected or coupled to the other element or layer, or intervening elements may be present.

Like reference numerals in the drawings refer to like elements. In addition, in the drawings, the thickness and the ratio and the dimension of the element are exaggerated for effective description of the technical contents. The term “and/or” includes any and all combinations of one or more of the associated items.

Terms such as “first”, “second”, and the like may be used to describe various components, but these components should not be limited by the terms. These terms are only used to distinguish one element from another. For instance, a first component may be referred to as a second component, or similarly, a second component may be referred to as a first component, without departing from the scope of the present disclosure. The singular expressions include plural expressions unless the context clearly dictates otherwise.

In addition, the terms such as “under”, “lower”, “on”, and “upper” are used for explaining associations of items illustrated in the drawings. The terms are used as a relative concept and are described with reference to the direction indicated in the drawings.

It should be understood that the terms “comprise” or “have” are intended to specify the presence of stated features, integers, steps, operations, elements, components, or combinations thereof in the disclosure, but do not preclude the presence or addition of one or more other features, integers, steps, operations, elements, components, or combinations thereof.

Unless otherwise defined, all terms (including technical and scientific terms) used herein have the same meaning as commonly understood by one of ordinary skilled in the art to which example embodiments belong. In addition, it will be further understood that terms, such as those defined in commonly-used dictionaries, should be interpreted as having a meaning that is consistent with their meaning in the context of the relevant art and will not be interpreted in an idealized or overly formal sense unless expressly so defined herein.

Hereinafter, embodiments of the inventive concept will be described with reference to the accompanying drawings.

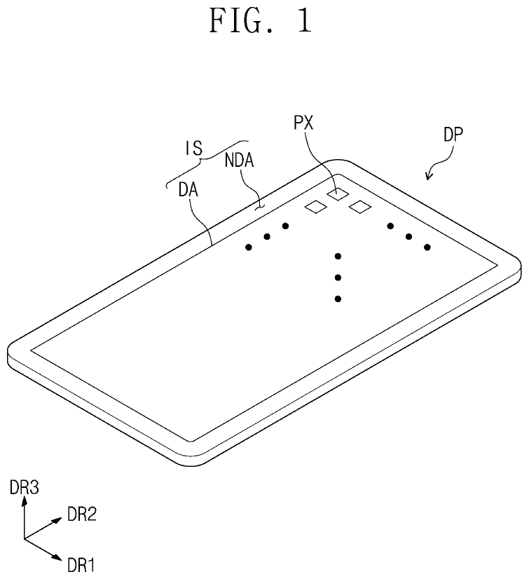

FIG. 1 is a perspective view of a display panel DP according to an embodiment.

Referring to FIG. 1, the display panel DP may be a device activated in response to an electrical signal. The display panel DP may be used in a small or medium-sized electronic device such as a monitor, a notebook computer, or a mobile phone as well as a large-sized electronic device such as a television.

The display panel DP may display an image through a display surface IS parallel to a plane defined by a first direction DR1 and a second direction DR2 that are orthogonal to each other. In the embodiment, a front surface (or a top surface) and a rear surface (or a bottom surface) of each member are defined on the basis of a third direction DR3 that is a normal direction to the display surface IS. The front surface and the rear surface may face each other in the third direction DR3.

A display surface IS may include a display area DA in which the image is displayed and a non-display area NDA in which the image is not displayed. Pixels (PX) are disposed in the display area DA, and the pixels PX are not disposed in the non-display area NDA.

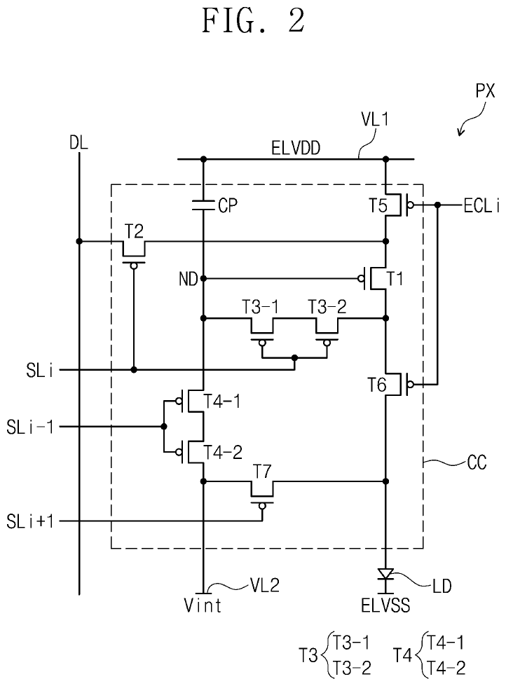

FIG. 2 is an equivalent circuit diagram of a pixel PX according to an embodiment.

The pixel PX may include a light emitting element LD, and a pixel circuit CC. The pixel circuit CC may include first to seventh transistors T1 to T7, and a capacitor CP. The pixel circuit CC controls a current amount flowing through the light emitting element LD in response to a data signal. The light emitting element LD may emit light in a prescribed luminance in response to the current amount provided from the pixel circuit CC.

Each of the first to seventh transistors T1 to T7 may include a source, a drain, a channel, and a gate. The source, the drain, and the channel may be respectively implemented in different regions in a semiconductor pattern. In the embodiment, each of the first to seventh transistors T1 to T7 is described as a P-type transistor. However, the embodiment is not limited thereto, and some of the first to seventh transistors T1 to T7 may be N-type transistors. The source and drain of the P-type transistor may respectively correspond to the drain and source of the N-type transistor.

The source of the first transistor T1 is in electrical communication with a first voltage line VL1 via the fifth transistor T5, and the drain of the first transistor T1 is in electrical communication with an anode of the light emitting element LD via the sixth transistor T6. The first transistor T1 may be referred to as a driving transistor. The first transistor T1 controls the amount of current flowing through the light emitting element LD in response to a voltage applied to the gate. The gate of the first transistor T1 may be described as a reference node ND.

The second transistor T2 is in electrical communication with a data line DL and the first transistor T1. In addition, the gate of the second transistor T2 is in electrical communication with an i-th scan line SLi. The second transistor T2 may be referred to as a switching transistor.

The third transistor T3 (T3-1, T3-2) is in electrical communication with the gate and drain of the first transistor T1. In the embodiment, two example third transistors T3-1, T3-2 are shown as being in series electrical communication with each other. However, the embodiment is not limited thereto, and n (where n is a natural number of 1 or greater) third transistors may be in electrical communication in series between the gate and drain of the first transistor T1. The gate of each of the third transistors T3-1, T3-2 is in electrical communication with the i-th scan line SLi.

The fourth transistor T4 (T4-1, T4-2) is in electrical communication between the reference node ND and a second voltage line VL2. In the embodiment, two example fourth transistors T4-1, T4-2 are shown as being in electrical communication in series. However, the embodiment is not limited thereto, and n (where n is a natural number of 1 or greater) fourth transistors may be in electrical communication between the reference node ND and the second voltage line VL2. The gate of each of the fourth transistors T4-1, T4-2 is in electrical communication with the (i−1)-th scan line SLi−1.

The fifth transistor T5 is in electrical communication between the first voltage line VL1 and the source of the first transistor T1. The gate of the fifth transistor T5 is electrically in electrical communication with an i-th light emission control line ECLi. The sixth transistor T6 is in electrical communication between the drain of the first transistor T1 and the anode of the light emitting element LD. In addition, the gate of the sixth transistor T6 is in electrical communication with the i-th light emission control line ECLi.

The seventh transistor T7 is in electrical communication between the second voltage line VL2 and the anode of the light emitting element LD. In addition, the gate of the seventh transistor T7 is in electrical communication with the (i+1)-th scan line SLi+1. The capacitor CP is disposed between the first voltage line VL1 and the reference node ND. The capacitor CP stores a voltage corresponding to the data signal. When the fifth transistor T5 and the sixth transistor T6 are turned on, the current amount flowing through the first transistor T1 may be determined according to the voltage stored in the capacitor CP. In addition, as shown in FIG. 2, a driving voltage ELVDD may be provided to the first voltage line VL1, an initialization voltage Vint may be provided to the second voltage line VL2, and a common voltage ELVSS may be provided to a cathode of the light emitting element LD.

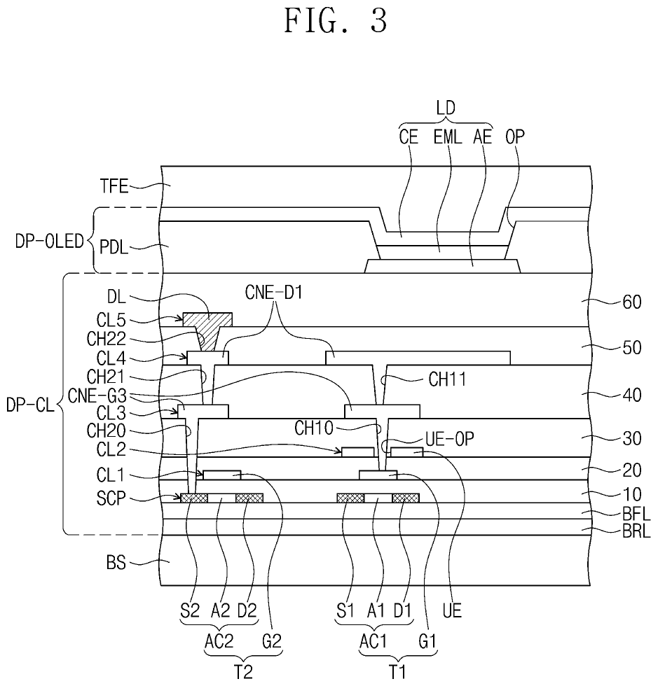

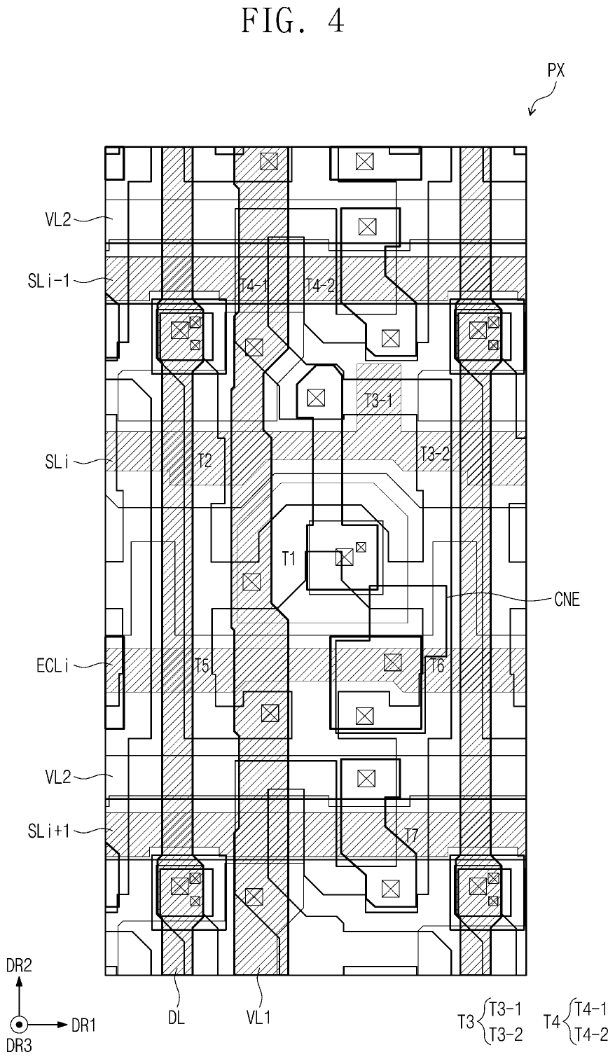

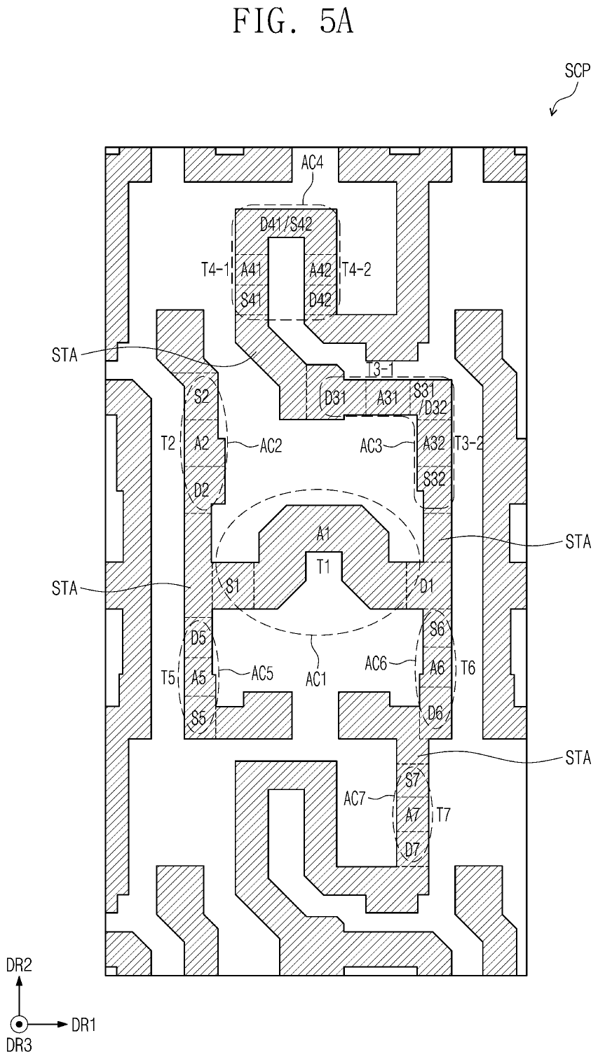

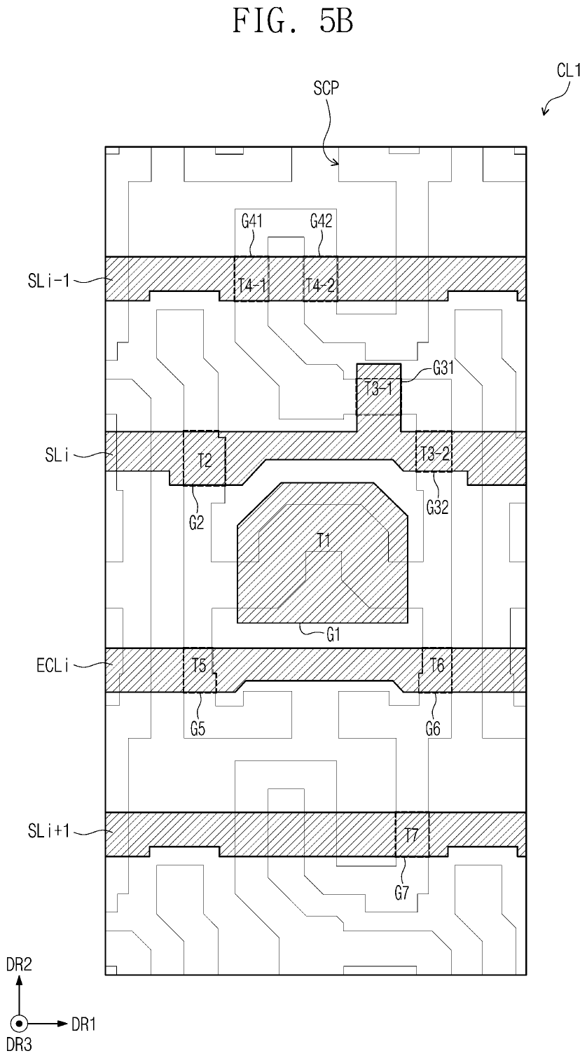

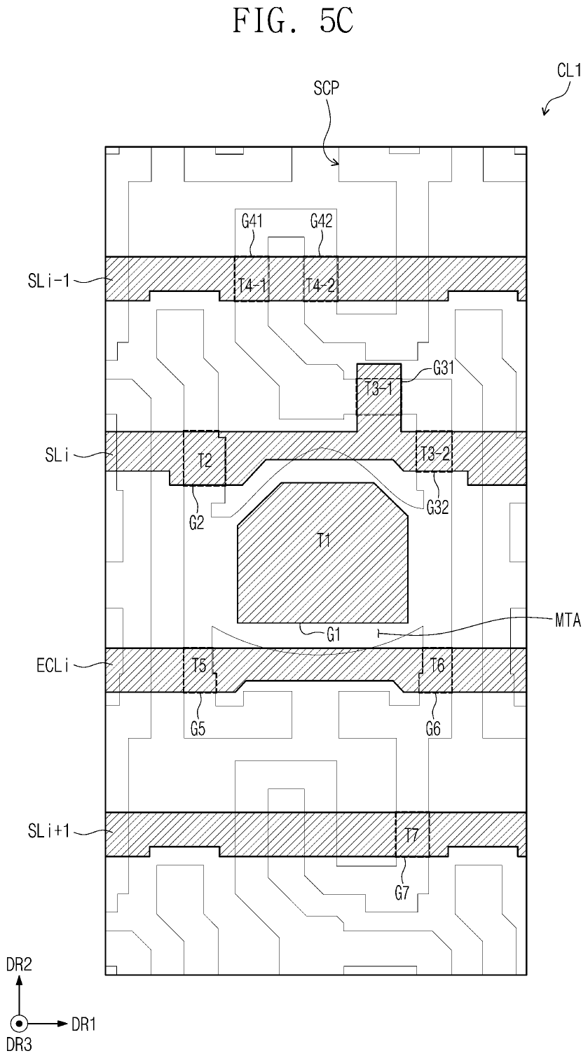

FIG. 3 is a cross-sectional view corresponding to the pixel PX of the display panel DP according to an embodiment. FIG. 4 is a plan view of pixel PX according to an embodiment. FIGS. 5A and 5B are plane views according to a lamination order of patterns included in the pixel according to an embodiment. FIG. 5C is a plan view of a bottom layer including a machining target area.

Referring to FIG. 3, the display panel DP may include a base layer BS, a circuit element layer DP-CL disposed on the base layer BS, a display element layer DP-OLED, and a thin-film encapsulation layer TFE. The circuit element layer DP-CL includes at least a plurality of insulation layers and circuit elements. The insulation layers to be described below may include organic layers and/or inorganic layers. The insulation layers may be formed through deposition processes.

Through photolithography processes, a contact hole in the insulation layers, semiconductor patterns, and conductive patterns may be formed. Patterns disposed on the same layer among the semiconductor patterns and the conductive patterns may be formed through the same photolithography process. The photolithography process includes a deposition process, a photoresist layer provision process, an exposure process, a development process, an etching process, and a photoresist layer removal process.

The base layer BS may include a synthetic resin layer. The synthetic resin layer may include a thermosetting resin. In an embodiment, the thermosetting resin may be a crosslinkable resin that is crosslinked by electromagnetic radiation (e.g., ultraviolet (UV) radiation). In particular, the synthetic resin layer may be a polyimide-based resin layer, but the material is not particularly limited thereto. The synthetic resin layer may include at least one of an acrylic-based resin, a methacrylic-based resin, a polyisoprene, a vinyl-based resin, an epoxy-based resin, a urethane-based resin, a cellulose-based resin, a siloxane-based resin, a polyamide-based resin, a parylene-based resin, or a combination thereof.

At least one inorganic layer is disposed on the top surface of the base layer BS. The inorganic layer may include at least any one of aluminum oxide, titanium oxide, silicon oxide, silicon nitride, silicon oxynitride, zirconium oxide, or hafnium oxide. The inorganic layer may be constituted with multiple layers. The multiple inorganic layers may constitute a barrier layer BRL and/or a buffer layer BFL that are described in detail below. The barrier layer BRL and the buffer layer BFL may be selectively disposed.

The barrier layer BRL prevents inflow of a foreign matter from the outside. The barrier layer BRL may include a silicon oxide layer and a silicon nitride layer. Each of them may be provided in plural, and the silicon oxide layers and the silicon nitride layers may alternate with one another in a laminate. For example, the barrier layer BRL may include a plurality of silicon oxide layers and a plurality of silicon nitride layers each of which alternate with one another in a laminate. The buffer layer BFL may enhance a bonding force between the base layer BS and a semiconductor pattern and/or a conductive pattern. The buffer layer BFL may include silicon oxide layers and silicon nitride layers. The silicon oxide layers and the silicon nitride layers may be alternately laminated.

A semiconductor pattern SCP may be disposed on the buffer layer BFL. The semiconductor pattern SCP may include an amorphous silicon semiconductor, a crystalline silicon semiconductor, or an oxide semiconductor. As shown in FIG. 3, the semiconductor pattern SCP may include a first semiconductor area AC1 and a second semiconductor area AC2. The first semiconductor area AC1 may include a source area S1, a channel area A1, and a drain area D1 of the first transistor T1, and the second semiconductor area AC2 may include a source area S2, a channel area A2, and a drain area D2 of the second transistor T2. The first semiconductor area AC1 and the second semiconductor area AC2 may include the same or different semiconductor materials. According to an embodiment, the first semiconductor area AC1 and the second semiconductor area AC2 may be disposed on different layers.

A first insulation layer 10 is disposed on the buffer layer BFL. The first insulation layer 10 covers the semiconductor pattern SCP. The first insulation layer 10 may be an organic layer or an inorganic layer. Second to sixth insulation layers 20 to 60 to be described below may also be organic layers or inorganic layers and are not particularly limited thereto. It is to be noted that the conductive layers CL1 through CL5 discussed below may comprise an “electrically conducting” material or a semiconducting material, while the first to sixth insulation layers 10 through 60 may comprise an “electrically insulating” material.

A first conductive layer CL1 is disposed on the first insulation layer 10. The first conductive layer CL1 may include a plurality of conductive patterns. In the embodiment, the gate G1 of the first transistor T1 and the gate G2 of the second transistor T2 are illustrated as the conductive patterns of the first conductive layer CL1.

The second insulation layer 20 covering the first conductive layer CL1 is disposed on the first insulation layer 10. A second conductive layer CL2 is disposed on the second insulation layer 20. The second conductive layer CL2 may include a plurality of conductive patterns. An upper electrode UE is shown as a conductive pattern of the second conductive layer CL2. The upper electrode UE may overlap the gate G1 of the first transistor T1, and an opening UE-OP may be disposed therein. The overlapping upper electrode UE and the gate G1 of the first transistor T1 define the capacitor CP (see FIG. 2).

The third insulation layer 30 covering the second conductive layer CL2 is disposed on the second insulation layer 20. A third conductive layer CL3 is disposed on the third insulation layer 30. The third conductive layer CL3 may include a plurality of conductive patterns. Connection electrodes CNE-G3 are shown as the conductive patterns of the third conductive layer CL3. One connection electrode CNE-G3 contacts the gate G1 of the first transistor T1 through a contact hole CH10 penetrating through the second insulation layer 20 and the third insulation layer 30. The contact hole CH10 passes the opening UE-OP. The other connection electrode CNE-G3 contacts the source area S2 of the second transistor T2 through a contact hole CH20 penetrating through the first insulation layer 10, the second insulation layer 20 and the third insulation layer 30.

The fourth insulation layer 40 covering the third conductive layer CL3 is disposed on the third insulation layer 30. A fourth conductive layer CL4 is disposed on the fourth insulation layer 40. Connection electrodes CNE-D1 are shown as the conductive patterns of the fourth conductive layer CL4. The connection electrodes CNE-D1 may respectively be in contact with corresponding connection electrodes CNE-G3 through contact holes CH11, CH21 penetrating through the fourth insulation layer 40.

The fifth insulation layer 50 covering the fourth conductive layer CL4 is disposed on the fourth insulation layer 40. A fifth conductive layer CL5 is disposed on the fifth insulation layer 50. The data line DL is shown as an example of the fifth conductive layer CL5. The data line DL may contact the corresponding connection electrode CNE-D1 through a contact hole CH22 penetrating through the fifth insulation layer 50.

The sixth insulation layer 60 covering the fifth conductive layer CL5 is disposed on the fifth insulation layer 50. The light emitting element LD is disposed on the sixth insulation layer 60. A first electrode AE of the light-emitting element LD may be disposed on the sixth insulation layer 60. The first electrode AE may be the anode. A pixel definition layer PDL is disposed on the sixth insulation layer 60.

An opening OP of the pixel definition layer PDL exposes at least a portion of the first electrode AE. The opening OP of the pixel definition layer PDL may define a light emitting area. A light emitting layer EML is disposed on the first electrode AE. In the embodiment, a patterned example light emitting layer EML is illustrated, but the light emitting layer EML may be commonly disposed in the plurality of pixels PX (see FIG. 1). The light emitting layer EML may generate white light or blue light. In addition, the light emitting layer EML may have a multilayer structure.

Although not shown, a hole transport layer may be further disposed between the first electrode AE and the light emitting layer EML. A hole injection layer may be further disposed between the hole transport layer and the first electrode AE. The hole transport layer or the hole injection layer may be commonly disposed in the plurality of pixels PX (see FIG. 1). A second electrode CE is disposed on the light emitting layer EML. Although not shown, an electron transport layer may be further disposed between the second electrode CE and the light emitting layer EML. An electron injection layer may be further disposed between the electron transport layer and the second electrode CE. The electron transport layer or the electron injection layer may be commonly disposed in the plurality of pixels PX (see FIG. 1).

The thin-film encapsulation layer TFE is disposed on the second electrode CE. The thin-film encapsulation layer TFE is commonly disposed in the plurality of pixels PX (see FIG. 1). In the embodiment, the thin-film encapsulation layer TFE directly covers the second electrode CE. In the embodiment, a capping layer directly covering the second electrode CE may be further disposed. The thin-film encapsulation layer TFE includes at least an inorganic layer or an organic layer. In an embodiment, the thin-film encapsulation layer TFE may include two inorganic layers and an organic layer interposed therebetween. In an embodiment, the thin-film encapsulation layer MB may include a plurality of inorganic layers and a plurality of organic layers alternately laminated.

Referring to FIG. 4, an example of the first to seventh transistors T1 to T7 of the pixels PX is shown. Additionally, the scan lines SLi−1, SLi, SLi+1, the i-th light emission control line ECLi, the first voltage line VL1, the second voltage line VL2, and the data line DL are shown. The pixel PX having the layout shown in FIG. 4 may be formed through a plurality of insulation deposition processes and a plurality of photolithography processes. FIGS. 5A and 5B show a state where some photolithography processes are performed in a region corresponding to the pixel PX.

Referring to FIG. 5A, the semiconductor pattern SCP may be disposed on the base layer BS (see FIG. 3). The semiconductor pattern SCP may be disposed directly on the buffer layer BFL. The semiconductor pattern SCP having designed numerical values and shape is formed through the photolithography processes. The semiconductor pattern SCP includes first to seventh semiconductor areas AC1 to AC7 corresponding to the first to seventh transistors T1 to T7 (see FIG. 2).

The first to seventh semiconductor areas AC1 to AC7 respectively include corresponding source areas S1 to S7, corresponding channel area A1 to A7, and corresponding drain areas D1 to D7. The source areas S1 to S7 and the drain areas D1 to D7 are areas in which doping concentrations increase through subsequent processes to substantially have conductivities. The channel areas A1 to A7 have low doping concentrations disposed between the source areas S1 to S7 and the drain area D1 to D7. Substantially, the sources and drains of each of the first to seventh transistors T1 to T7 are respectively defined by the source areas S1 to S7 and the drain areas D1 to D7 of the first to seventh semiconductor areas AC1 to AC7. As shown in FIG. 5A, the third semiconductor area AC3 may include a source area S31, a channel area A31, and a drain area D31 of a third transistor T3-1 and a source area S32, a channel area A32, and a drain area D32 of a third transistor T3-2, and the fourth semiconductor area AC4 may include a source area S41, a channel area A41, and a drain area D41 of a fourth transistor T4-1 and a source area S42, a channel area A42, and a drain area D42 of a fourth transistor T4-2.

The first to seventh semiconductor areas AC1 to AC7 may have an integrated shape. The source areas S1 to S7 and the drain areas D1 to D7 of adjacent semiconductor areas among the first to seventh semiconductor areas AC1 to AC7 may not be divided from each other. In FIG. 5A, for convenience of description, the source areas S1 to S7 and the drain areas D1 to D7 of the adjacent semiconductor areas are shown as divided. In addition, signal delivery areas STA are shown disposed between the source areas S1 to S7 and the drain areas D1 to D7 of different semiconductor areas among the first to seventh semiconductor areas AC1 to AC7, but the embodiment is not limited thereto. Substantially, the signal delivery areas STA may have the same doping concentration as that of the source areas S1 to S7 or the drain areas D1 to D7.

Referring to FIG. 5B, the conductive patterns of the first conductive layer CL1 may be disposed on the first insulation layer 10 (see FIG. 3). The first insulation layer 10 disposed on the buffer layer BFL (see FIG. 3), and then the conductive patterns of the first conductive layer CL1 may be disposed on the first insulation layer 10 through photolithography processes. The first conductive layer CL1 may include the scan lines SLi−1, SLi, SLi+1, the i-th light emission control line ECLi, and the first gate G1 extending in the first direction DR1.

A portion of the i-th scan line SLi overlapping the semiconductor pattern SCP may be the gate G2 of the second transistor T2, another portion of the i-th scan line SLi may be the gate G31 of the one third transistor T3-1, and another portion of the i-th scan line SLi may be the gate G32 of the other third transistor T3-2.

In FIG. 5B, the gates G41, G42 of the fourth transistors T4-1, T4-2 disposed in the (i−1)-th scan line SLi−1 are shown, the gate G7 of the seventh transistor T7 disposed in the (i+1)-th scan line SLi+1 is shown, the gate G5 of the fifth transistor T5 and the gate G6 of the sixth transistor T6 disposed in the i-th light emission control line ECLi are shown.

FIG. 5C shows the semiconductor pattern SCP including a machining target area MTA. The first insulation layer 10 (see FIG. 3) is disposed on the semiconductor pattern SCP including the machining target area MTA, and then the conductive patterns of the first conductive layer CL1 may be disposed on the first insulation layer 10. An exemplary state is illustrated where the machining target area MTA is detected after the conductive patterns of the first conductive layer CL1 are formed. The machining target area MTA is produced because a semiconductor layer or a metal layer is not patterned to have the designed numerical values or shape. The machining target area MTA should have been patterned as the first semiconductor area AC1 including the source area S1, channel area A1, and drain area D1 of the first transistor T1 as shown in FIGS. 5A and 5B, but the semiconductor layer is not patterned as designed due to errors in photolithography processes.

In this way, when the machining target area MTA of the bottom layer is found after the top layer is formed, the machining target area MTA disposed lower than the top layer may be machined through subsequent processes. Here, the top layer should be machined first. The bottom layer in the embodiment is described as the semiconductor pattern SCP, and the top layer is described as the first conductive pattern CL1. However, the embodiment is not limited thereto. In an embodiment, the bottom layer may be another conductive layer. For example, referring to FIG. 3, after the fourth conductive layer CL4 is formed, a machining target area of the third conductive layer CL3 or a machining target area of the second conductive layer CL2 may be detected. Then, the machining target area of the third conductive layer CL3 or the machining target area of the second conductive layer CL2 may be machined through subsequent processes.

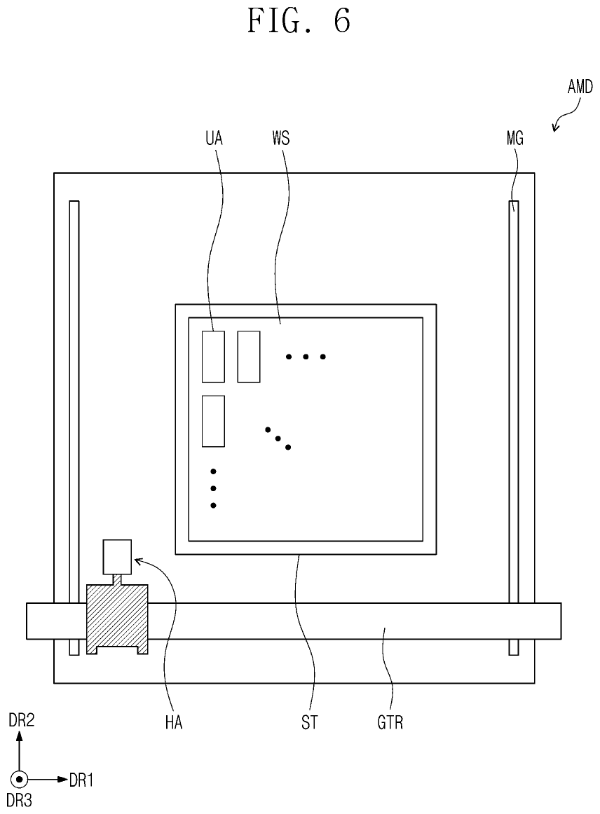

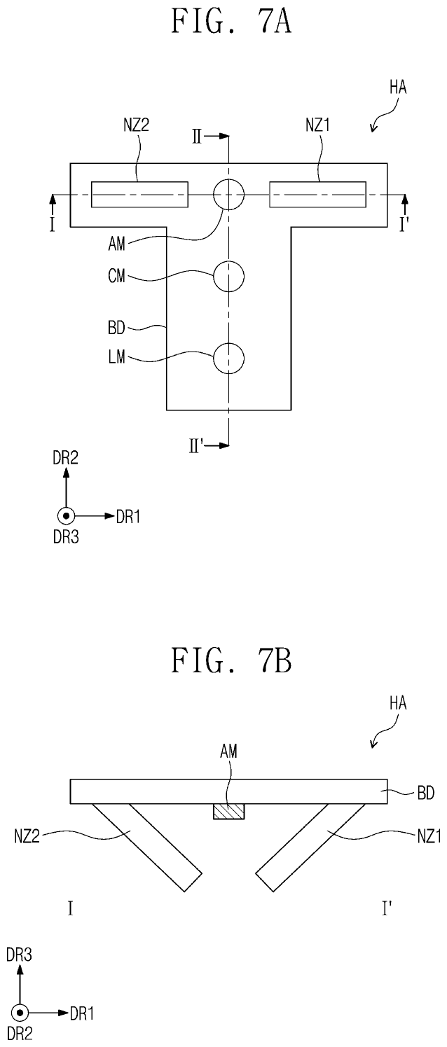

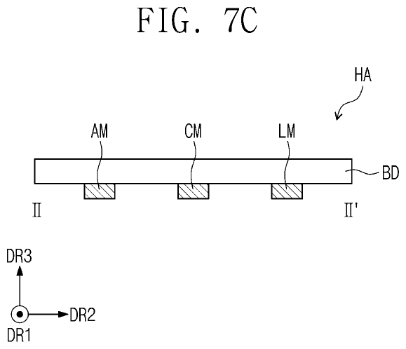

FIG. 6 is a plane view of a manufacturing apparatus AMD according to an embodiment. FIGS. 7A to 7C show a head assembly HA of a manufacturing apparatus AMD according to an embodiment.

In an embodiment, when a machining target area MTA is detected during the manufacturing of a display panel, a work substrate WS may be moved to the manufacturing apparatus AMD in FIG. 6. Alternatively, according to the embodiment, in order to detect the machining target area MTA during manufacturing the display panel, the work substrate WS may be moved to the manufacturing apparatus AMD in FIG. 6.

Referring to FIG. 6, the manufacturing apparatus AMD may include a stage ST supporting the work substrate WS, a gantry GTR movable in the second direction DR2, and the head assembly HA combined with the gantry GTR so as to be movable in the first direction DR1. The gantry GTR may move in the second direction DR2 according to a movement guide MG.

The work substrate WS includes a plurality of cell areas UA. After completion of the manufacturing process, the plurality of cell areas UA are cut to provide the display panel DP (see FIG. 1). In at least one of the plurality of cell areas UA, the machining target area MTA described in FIG. 5C may be detected.

Referring to FIGS. 7A to 7C, the head assembly HA may include a body part BD, a camera module CM combined with the body part BD, a laser module LM combined with the body part BD, a curing module AM combined with the body part BD, an electrohydrodynamic (EHD) insulation ink nozzle NZ1 configured to provide an insulation ink, and an EHD metal ink nozzle NZ2 configured to provide a metal ink. Although not shown in detail, the body part BD may be configured to be movable in the third direction DR3. For example, the body part BD may be combined to the gantry GTR in FIG. 6 by means of a crane structure so as to be movable in the third direction DR3. The term “electrohydrodynamic” pertains to the application of an electrical field to control the motion of particles in the ink.

The body part BD may constitute the framework of the head assembly HA and include a frame configured to fix other components. The camera module CM may include a high-dry lens to identify the measures of the semiconductor patterns and the conductive patterns in FIG. 4 and detect the machining target area MTA shown in FIG. 5C.

The laser module LM is used to remove the insulation layers, the conductive patterns or the semiconductor patterns. The laser module LM may include a femtosecond laser device. The curing module AM may include an optical lamp such as a laser lamp, or a sintering laser device.

The EHD insulation ink nozzle NZ1 may apply an electric pulse of a certain period to spread an insulation ink. The insulation ink may include silicon oxide, silicon nitride, silicon oxynitride, or a combination thereof. The EHD metal ink nozzle NZ2 may apply an electric pulse having a certain period to spread a metal ink. The metal ink may include silver but is not limited thereto. The metal ink may include gold, white gold, copper, or the like. Combinations of the foregoing metals may be used in the metal ink. For example, silver could be used along with either or all of gold, white gold and copper in a metal ink. The metal ink may include particles of the above-described metal and organic binders. The inner radius of the EHD metal ink nozzle NZ2 may be about 0.5 μm, and a conductive pattern having a thickness of about 2 μm or smaller may be formed.

Disposition relationships among the camera module CM, the laser module LM, the curing module AM, the EHD insulation ink nozzle NZ1, and the EHD metal ink nozzle NZ2 shown in FIGS. 7A to 7C is merely an example and is not particularly limited. FIG. 7B is a cross-section view taken along a line I-I′ in FIG. 7A, and FIG. 7C is a cross-section view taken along a line II-II′ in FIG. 7A. When viewed in a plan view, the curing module AM may be disposed between the EHD insulation ink nozzle NZ1 and the EHD metal ink nozzle NZ2 in the first direction DR1. Both the insulation ink and the metal ink may be cured by means of one curing module AM.

Referring to FIG. 7B, the EHD insulation ink nozzle NZ1 may be combined to the body part BD so as to be inclined at about 30° to about 60° with respect to the work substrate WS (see FIG. 6). In addition, the EHD metal ink nozzle NZ2 may be combined to the body part BD so as to be inclined at about 30° to about 60° with respect to the work substrate WS (see FIG. 6).

When the slope between the EHD insulation ink nozzle NZ1 or the EHD metal ink nozzle NZ2, and the work substrate WS (see FIG. 6) is smaller than about 30°, it is not easy to discharge the ink from the nozzle. Since the viscosity of the ink is high, the ink inside the nozzle tends to clog the nozzle, because the particles bind to each other. When the slope between the EHD insulation ink nozzle NZ1 or the EHD metal ink nozzle NZ2, and the work substrate WS (see FIG. 6) is greater than about 60°, it is not easy to restrict the ink to a smaller area. It is because the greater the angle, the more rapidly the ink exits the nozzle with the result is that the ink spreads wider when it is provided to the work substrate WS.

In an embodiment, the slope of the EHD insulation ink nozzle NZ1 with respect to the work substrate WS (see FIG. 6) may be the same as that of the EHD metal ink nozzle NZ2 with respect to the work substrate WS. In an embodiment, the slopes of the EHD insulation ink nozzle NZ1 and the EHD metal ink nozzle NZ2 may be about 45°.

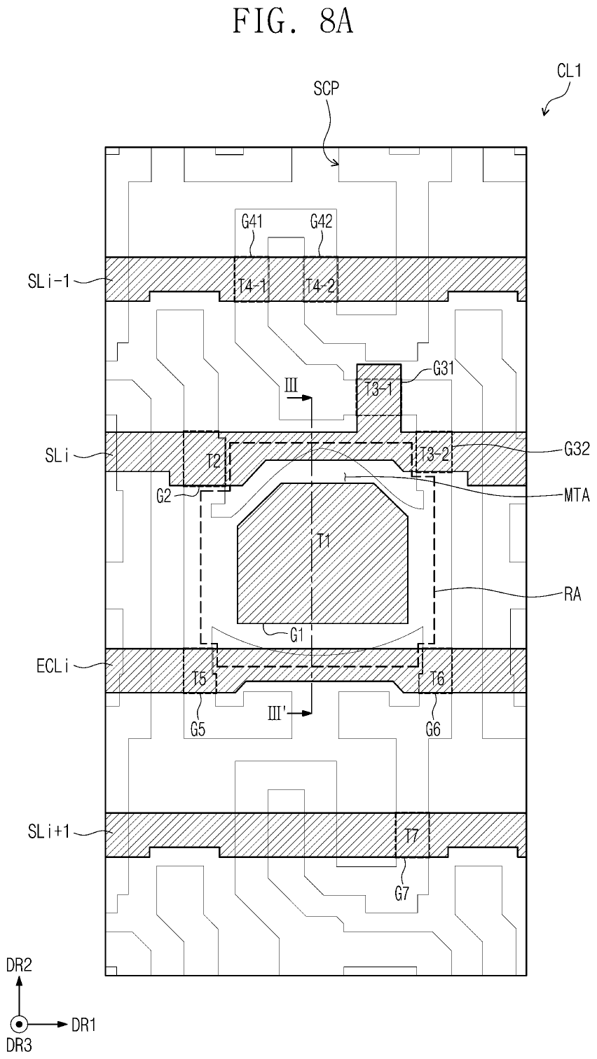

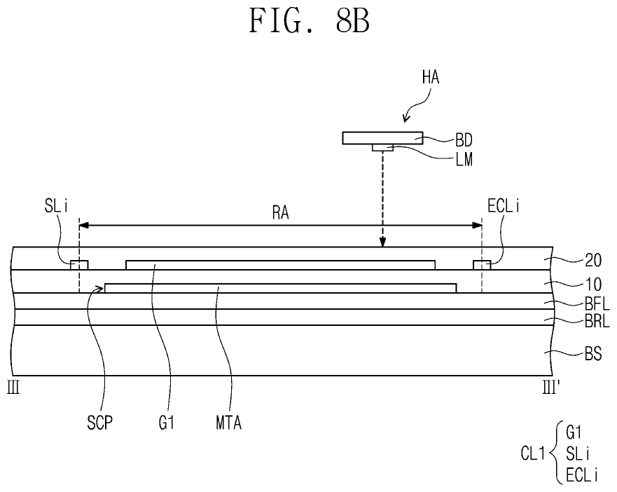

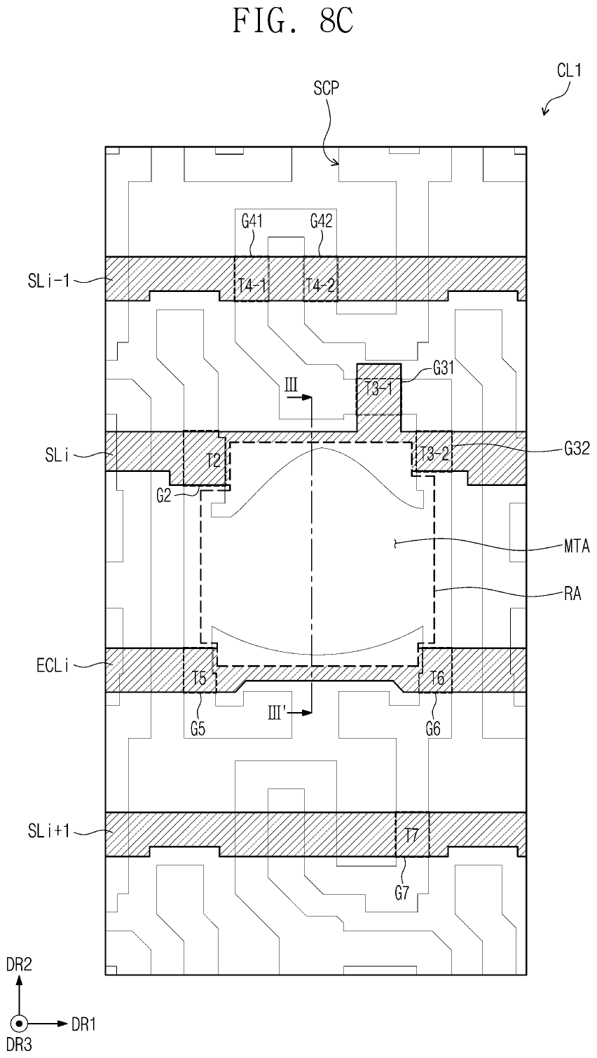

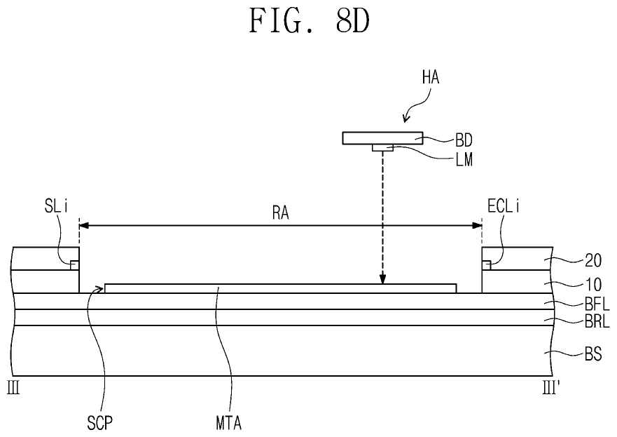

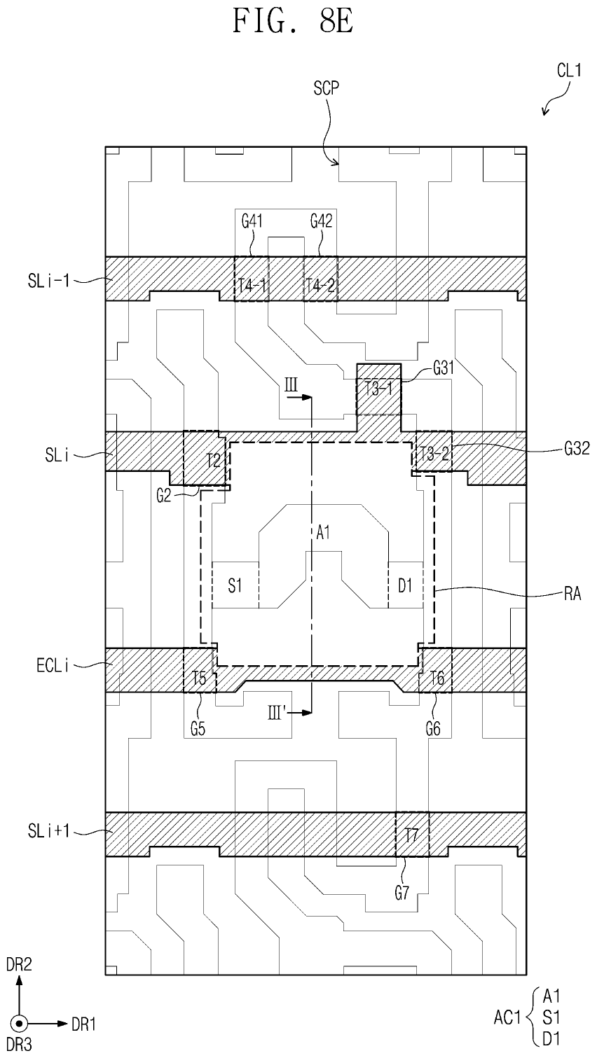

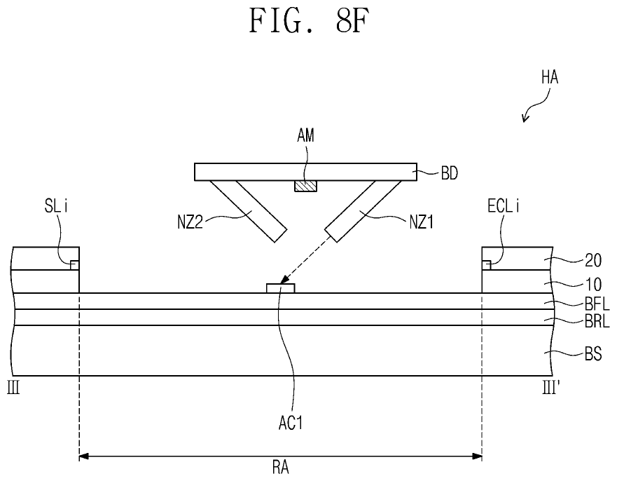

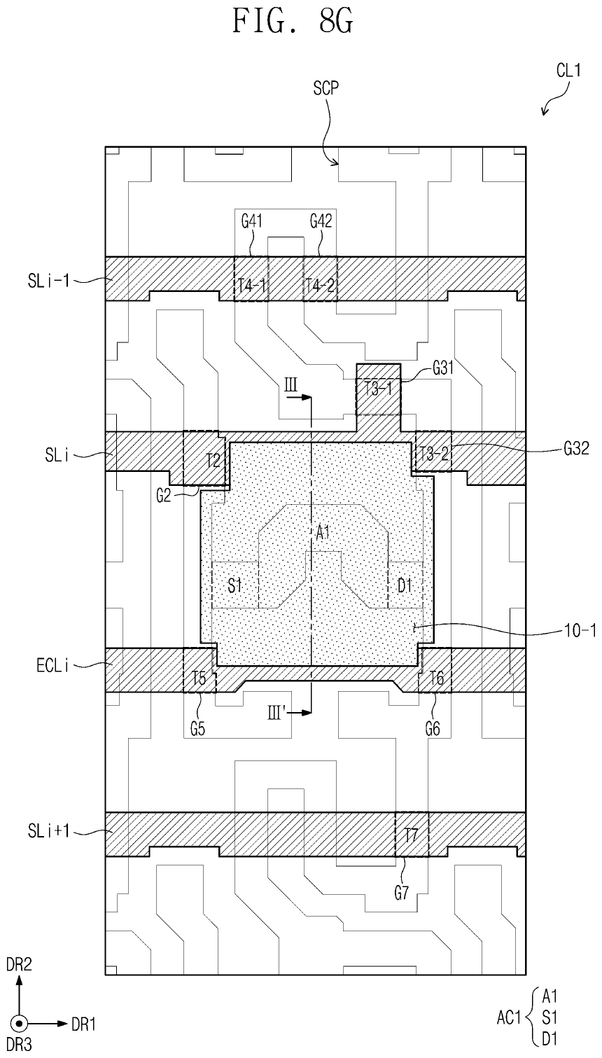

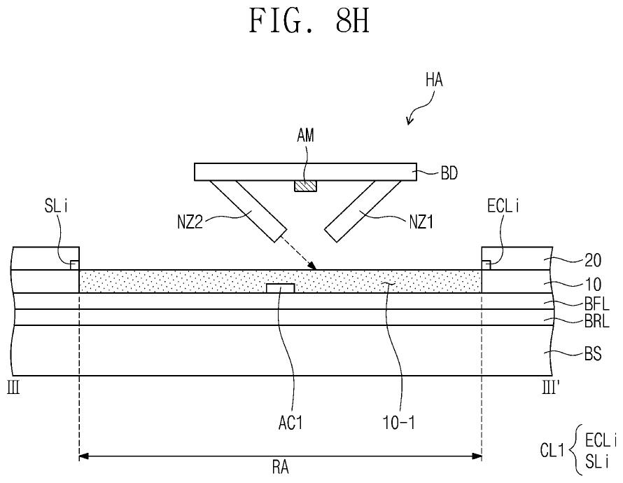

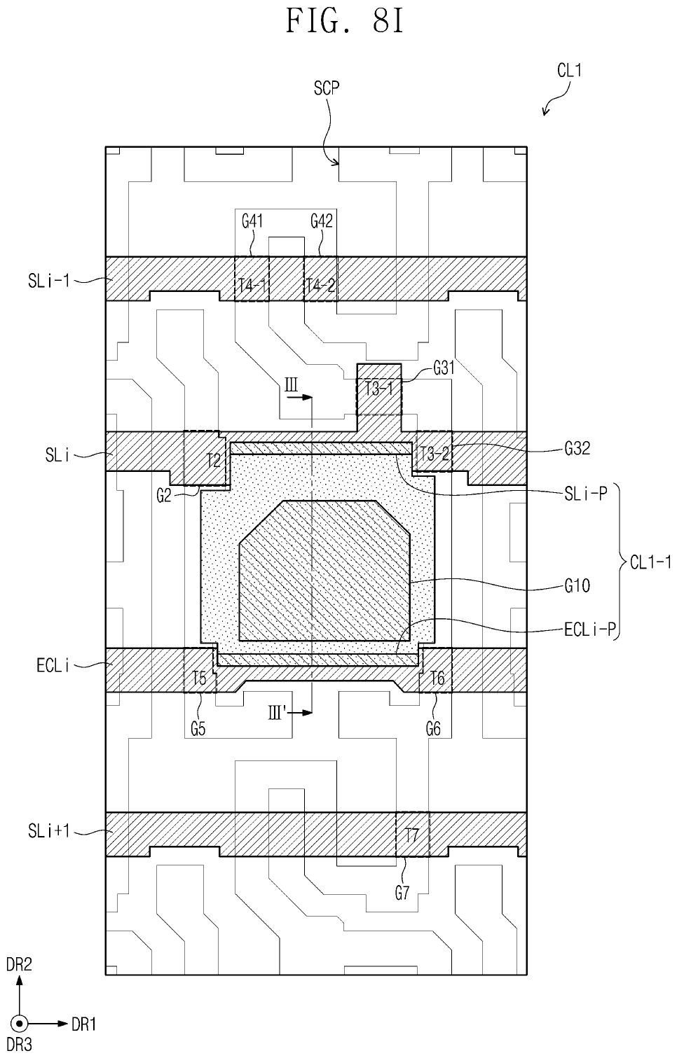

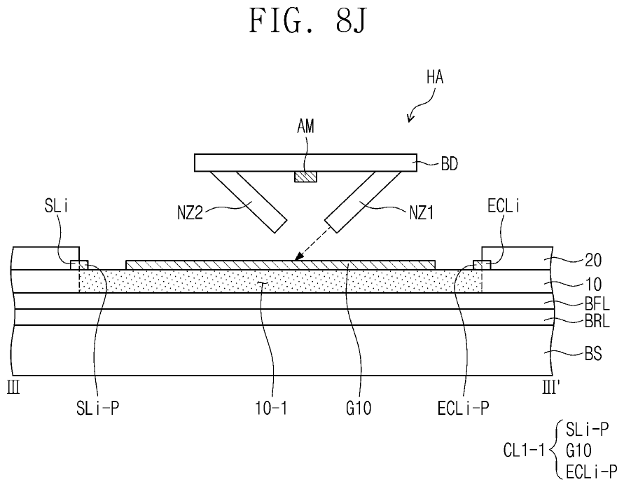

FIGS. 8A to 8J show a manufacturing the display panel DP according to an embodiment. FIGS. 8A to 8J show portions of the layout of the pixel PX in FIG. 4. In addition, FIGS. 8A to 8J illustrate the display panel manufacturing method using the head assembly HA described with reference to FIGS. 6 and 7C.

As shown in FIG. 8A, the machining target area MTA is detected. The cell areas UA of the work substrate WS in FIG. 6 is photographed using the camera module CM, and the machining target area MTA is specified. The machining target area MTA may be detected from some of the cell areas UA.

A step for detecting the machining target area MTA may be executed periodically in a display panel manufacturing processes. In the embodiment, a step for detecting the machining target area MTA is described to be performed after the second insulation layer 20 in FIGS. 3 and 5C is formed.

FIG. 8B shows a cross-section view taken along a line in FIG. 8A. As shown in FIG. 8B, the head assembly HA is arranged on the machining target area MTA. First, a structure disposed on the top of the machining target area MTA is removed. A partial area, overlapping the machining target area MTA, of the second insulation layer 20 is removed using the laser module LM. An area corresponding to the machining target area MTA is defined as a reference area RA. The reference area RA may have a greater area than the machining target area MTA, and may be set so that the machining target area MTA is disposed inside the reference area RA. The reference area RA of the second insulation layer 20, the reference area RA of the first conductive layer CL1, and the reference area RA of the first insulation layer 10 may be sequentially or concurrently removed. The reference area RA of the first conductive layer CL1 may include the gate G1 of the first transistor T1 (see FIG. 4), a portion of the i-th scan line SLi, and a portion of the i-th light emission control line ECLi. FIG. 8C shows a plane in which the reference area RA of the second insulation layer 20, the reference area RA of the first conductive layer CL1, and the reference area RA of the first insulation layer 10 are removed.

As shown in FIG. 8D, the machining target area MTA may be exposed to the outside. The head assembly HA is arranged on the machining target area MTA. A laser beam is emitted to the machining target area MTA to provide a bottom pattern from the machining target area MTA. As shown in FIG. 8E, in the embodiment, the bottom pattern may be the first semiconductor pattern AC1 in FIG. 5A. The laser beam is emitted to provide a curved bottom pattern from the machining target area MTA. The laser beam machining is suitable for patterning the curved shape, and, unlike the photolithography process, may be suitable for providing a pattern having a smaller line-width and a small area.

As shown in FIGS. 8F and 8G, an insulation pattern 10-1 is formed in the reference area RA of the first insulation layer 10. The EHD insulation ink nozzle NZ1 supplies an insulation ink to the reference area RA of the first insulation layer 10. The EHD insulation ink nozzle NZ1 is spaced apart from the first insulation layer 10 by about 5 μm so that when the EHD insulation ink nozzle NZ1 stops discharging the insulation ink, insulation ink droplets are prevented from being connected to each other (i.e., they do not contact each other) between the insulation ink on the buffer layer BFL and the EHD insulation ink nozzle NZ1. In other words, when the EHD insulation ink nozzle NZ1 pauses, the EHD insulation ink nozzle NZ1 is spaced apart from the first insulation layer 10 by a prescribed interval so that the insulation ink on the buffer layer BFL is spaced apart from the EHD insulation ink nozzle NZ1.

Then, the curing module AM (see FIG. 7A) cures the insulation ink. In order to align the curing module AM to an area in which the insulation ink is formed, the head assembly HA may be moved. The insulation pattern 10-1 may include the substantially same material as that of the first insulation layer 10. The cured insulation pattern 10-1 may have the substantially same thickness as that of the first insulation layer 10.

As shown in FIGS. 8H and 81, a compensation pattern CL1-1 is formed in the reference area RA of the first conductive layer CL1. The EHD metal ink nozzle NZ2 supplies a metal ink on the insulation pattern 10-1. The EHD metal ink nozzle NZ2 is spaced apart from the first conductive layer CL1 by about 5 μm so that when the EHD metal ink nozzle NZ2 stops discharging the metal ink, metal ink droplets are prevented from being connected to each other between the metal ink on the first insulation layer 10 and the EHD metal ink nozzle NZ2. In other words, there is no contact between the metal ink droplets on the first insulation layer 10 and the EHD metal ink nozzle NZ2.

The EHD metal ink nozzle NZ2 provides the metal ink only to an area corresponding to a portion in which the first conductive layer CL1 in FIG. 8B is removed. Accordingly, the metal ink is provided to an area narrower than the insulation pattern 10-1 in a bottom side.

Then, the curing module AM (see FIG. 7A) cures the metal ink provided on the insulation pattern 10-1. The compensation pattern CL1-1 may include a material having a higher electrical conductivity than the first conductive layer CL1. The compensation pattern CL1-1 having a lower resistance is formed in consideration of contact resistance between the first conductive layer CL1 and the compensation pattern CL1-1.

The compensation pattern CL1-1 may include a control electrode G10 corresponding to the gate G1, which has been removed, of the first transistor T1, a first line part SLi-P corresponding to a part from which the i-th scan line SLi has been removed, and a second line part ECLi-P corresponding to a part from which the i-th light emission control line ECLi has been removed. The line widths of the i-th scan line SLi and the i-th light emission control line ECLi may be about 3 μm or smaller, and thus, the line widths of the first line part SLi-P and the second line part ECLi-P may also be about 3 μm or smaller. The EHD metal ink nozzle NZ2 may be suitable for providing a pattern having a narrow line-width.

Then, as shown in FIGS. 8J, an insulation pattern is formed in the reference area RA of the second insulation layer 20. This insulation pattern may be formed by a substantially same method as that for providing the insulation pattern 10-1 described with reference to FIGS. 8F and 8G.

Thereafter, the photolithography and insulation layer deposition processes are repeated to provide the second conductive layer CL2, the third insulation layer 30, the third conductive layer CL3, the fourth insulation layer 40, the fourth conductive layer CL4, the fifth insulation layer 50, the fifth conductive layer CL5, and the sixth insulation layer 60 shown in FIG. 3. In addition, the pixel definition layer PDL, the light emitting element LD, and the thin-film encapsulation layer TFE may be formed.

According to the above-described, a partial area of the bottom layer, which is not patterned in a designed shape in the photolithography processes, may be machined in subsequent processes.

The machining target area is laser-patterned to provide a semiconductor pattern or a conductive pattern having the designed shape.

The manufacturing apparatus, into which various modules are integrated, may reduce a manufacturing time of the display panel.

While this invention has been described with reference to exemplary embodiments thereof, it will be clear to those of ordinary skilled in the art to which the invention pertains that various changes and modifications may be made to the described embodiments without departing from the spirit and technical area of the invention as defined in the appended claims and their equivalents.

Thus, the scope of the inventive concept shall not be restricted or limited by the foregoing description, but be determined by the broadest permissible interpretation of the following claims.

What is claimed is:

1. A display panel manufacturing method comprising:
detecting a machining target area of a bottom layer;
removing an area, overlapping the machining target area, of a top layer disposed on the bottom layer;
removing an area, overlapping the machining target area, of an insulation layer disposed on the bottom layer;
emitting a laser beam to the machining target area of the bottom layer to form a bottom pattern from the machining target area;
forming an insulation pattern in the removed area of the insulation layer; and
forming a compensation pattern in the removed area of the top layer,
wherein the bottom layer comprises a semiconductor material or a conductive material, and the top layer comprises a conductive material.

2. The display panel manufacturing method according to claim 1,
wherein the bottom layer comprises the semiconductor material,
the bottom pattern comprises a channel area of a transistor, and
the compensation pattern comprises a control electrode of the transistor.

3. The display panel manufacturing method according to claim 1, wherein the bottom pattern has a curved shape in a plan view.

4. The display panel manufacturing method according to claim 1, wherein the insulation pattern has a substantially same thickness as that of the insulation layer.

5. The display panel manufacturing method according to claim 4, wherein the insulation pattern comprises a substantially same material as that of the insulation layer.

6. The display panel manufacturing method according to claim 1, wherein the compensation pattern comprises a material having a higher electrical conductivity than the top layer.

7. The display panel manufacturing method according to claim 1, wherein the compensation pattern constitutes a portion of a scan line.

8. The display panel manufacturing method according to claim 7, wherein a line-width of the scan line is about 3 μm or smaller.

9. The display panel manufacturing method according to claim 1, wherein the forming of the insulation pattern comprises:
providing an insulation ink to the removed area of the insulation layer; and
curing the insulation ink.

10. The display panel manufacturing method according to claim 9, wherein the insulation ink is provided from an electrohydrodynamic insulation ink nozzle.

11. The display panel manufacturing method according to claim 10, wherein the electrohydrodynamic insulation ink nozzle is spaced apart from the insulation layer by about 5 μm or greater.

12. The display panel manufacturing method according to claim 9, wherein the insulation ink comprises silicon oxide, silicon nitride, silicon oxynitride, or a combination thereof.

13. The display panel manufacturing method according to claim 1, wherein the forming of the compensation pattern comprises:
providing a metal ink to the removed area of the top layer; and
curing the metal ink.

14. The display panel manufacturing method according to claim 13, wherein the metal ink is provided from an electrohydrodynamic metal ink nozzle.

15. The display panel manufacturing method according to claim 14, wherein the electrohydrodynamic metal ink nozzle is spaced apart from the top layer by about 5 μm or greater.

16. The display panel manufacturing method according to claim 13, wherein the metal ink comprises silver.

17. A display panel manufacturing apparatus comprising:
a body part;
a camera module combined to the body part;
a laser module combined to the body part;
a curing module combined to the body part;
an electrohydrodynamic insulation ink nozzle configured to provide an insulation ink; and
an electrohydrodynamic metal ink nozzle configured to provide a metal ink,
wherein the electrohydrodynamic insulation ink nozzle is combined to the body part so as to be inclined with respect to a work substrate at an angle of about 30° to about 60°, and
wherein the electrohydrodynamic metal ink nozzle is combined to the body part so as to be inclined with respect to the work substrate at an angle of about 30° to about 60°.

18. The display panel manufacturing apparatus according to claim 17, wherein, with respect to the work substrate, a slope of the electrohydrodynamic insulation ink nozzle is substantially same as that of the electrohydrodynamic metal ink nozzle.

19. The display panel manufacturing apparatus according to claim 17, wherein, when viewed on the work substrate, the curing module is disposed between the electrohydrodynamic insulation ink nozzle and the electrohydrodynamic metal ink nozzle.

20. The display panel manufacturing apparatus according to claim 17, further comprising:
a gantry movable in a first direction,
wherein the body part is combined to the gantry so as to be movable in a second direction that is orthogonal to the first direction.
